(19) United States
(12) Patent Application Publication
(10) Pub. No.: US 2021/0141854 A1
(43) Pub. Date: May 13, 2021

(54) Fourier Analysis Method with Variable Sampling Frequency

(71) Applicant: Harbin Institute of Technology, Harbin (CN)

(72) Inventors: Jiwei CAO, Harbin (CN); Liyi LI, Harbin (CN); Chengming ZHANG, Harbin (CN); Jiaxi LIU, Harbin (CN); Mingyi WANG, Harbin (CN)

(21) Appl. No.: 17/152,844

(22) Filed: Jan. 20, 2021

Related U.S. Application Data
(63) Continuation of application No. PCT/CN2020/076318, filed on Feb. 23, 2020.

(30) Foreign Application Priority Data
Apr. 28, 2019 (CN) 2019103496139

(51) Int. Cl. G06F 17/14

(52) U.S. Cl. CPC G06F 17/14; G01R 23/16

(57) ABSTRACT

The disclosure discloses a Fourier analysis method with a variable sampling frequency, including the following steps: S100 preliminarily sampling a to-be-analyzed signal by comparing an initially set sampling frequency, and further analyzing its fundamental frequency and fundamental amplitude value by Fourier analysis; S200 preliminarily judging the fundamental amplitude value obtained through analysis to determine a sampling frequency meeting integer period truncation, and resampling the signal; S300 performing Fourier analysis on the sampled signal, and determining an optimum sampling frequency, i.e., an optimum sampling frequency both meeting the integer period truncation and meeting no spectrum leakage, by a three-spectral line method; and S400 resampling the signal to obtain a frequency and amplitude value composition of each harmonic. The disclosure can realize high-precision and high-frequency signal acquisition and analysis by using a smaller sampling frequency, the cost of an acquisition system is reduced, and an analysis speed is accelerated.

### TECHNICAL FIELD

The disclosure herein belongs to the field of high-frequency signal test, and more particularly relates to a Fourier analysis method with a variable sampling frequency.

### BACKGROUND

The most common Fourier analysis is discrete Fourier transform (DFT) and fast Fourier transform (FFT). The DFT is an important harmonic analysis tool, can perform mathematical transformation on a sampling sequence of complex signals to separate fundamental signals from each harmonic signal. Generally, in order to ensure a frequency resolution, a sampling sequence length N needs to be increased. When an N value is greater, the DFT needs N2-time complex multiplication operation, and the required time is too long. The requirements on hardware may be greatly increased to ensure good real-time performance.

The FFT algorithm adopts a butterfly operation mode, and can realize harmonic detection in a short time, but the frequency resolution is low, and synchronous sampling and integer period truncation are required. If accurate synchronous sampling can be guaranteed, the available measurement accuracy of the FFT on harmonic waves is very high. However, the measurement of inter-harmonics depends on the frequency resolution. Generally, window lengths and sampling frequencies set by commercial power analyzers in compliance with IEC standards can only meet the frequency resolution in a range of 1 to 10 Hz, but it is often insufficient for inter-harmonic measurement of non-integer frequencies. Under the condition of non-synchronous sampling, errors of amplitude value and frequency measurement may be greatly increased due to inherent spectrum leakage and fence effect of the Fourier method, but it is difficult to realize strict synchronous sampling in practical engineering application, so how to reduce the spectrum leakage and fence effect is a research focus of scholars worldwide.

Analysis results of the Fourier method are greatly influenced by the spectrum leakage and fence effect, and they are complementary to each other. Only when a measured frequency component just coincides with a frequency axis unit, accurate analysis results can be obtained. Generally, existing harmonic analysis instruments and analysis methods may realize the precondition by using dual limitations of synchronous sampling and fence effect in the low-frequency field, but in fact, a strong constraint is added to the sampling condition, and an effective action space of the sampling frequency is reduced, so that the analysis in the high-frequency field may be limited by the sampling frequency.

In order to make the measured frequency coincide with a frequency axis unit point as much as possible, the common harmonic analysis algorithm are required to meet two conditions of synchronous sampling and integer period truncation. For the strict synchronous sampling, the sampling frequency is integer times of all frequency components. Otherwise, once the sampling frequency forms non-synchronous sampling of a certain harmonic, all spectral line results of Fourier analysis may be influenced. In practical engineering, the signal contains harmonics and inter-harmonics, the kinds of frequency components are various, and the frequency of each component is unknown, so it is difficult to achieve strict synchronous sampling. At the same time, integer period truncation needs wave filtering by instruments at an earlier stage to determine the fundamental period so as to calculate the truncation time window length. Under the condition that PWM is used or noise exists, large amplitude vibration at a zero crossing point of a waveform may cause measurement inaccuracy of the fundamental period. If a filter is added and used, the amplitude value of a main component may be reduced to a certain extent

A necessary and sufficient condition that no spectrum leakage occurs is that the measured frequency coincides with the frequency unit, and synchronous sampling and integer period truncation are derived conditions for realizing the precondition. For high-speed motors with operating frequencies up to hundreds or even thousands of Hertz, a limit of the existing hardware sampling frequency may be exceeded if a least common multiple of each harmonic number is solved to achieve synchronous sampling.

Therefore, by aiming at this condition, the disclosure provides a novel Fourier decomposition method with a variable sampling frequency, so as to improve the precision of the Fourier decomposition method, and effectively reduce the spectrum leakage and fence effect on high-frequency signals, especially harmonic signals.

### SUMMARY

In order to solve the problems of analysis acquisition and analysis of high-frequency signals of a high-speed motor, the disclosure provides a Fourier analysis method with a variable sampling frequency so as to improve the precision of a Fourier decomposition method and effectively reduce the spectrum leakage and fence effect on high-frequency signals, especially harmonic signals.

The disclosure is realized by the following technical solution: a Fourier analysis method with a variable sampling frequency includes the following steps:

S100 preliminarily sampling a to-be-analyzed signal by comparing an initially set sampling frequency, and further analyzing its fundamental frequency and fundamental amplitude value by Fourier analysis;

S200 preliminarily judging the fundamental amplitude value obtained through analysis to determine a sampling frequency meeting integer period truncation, and resampling the signal;

S300 performing Fourier analysis on the sampled signal, and determining an optimum sampling frequency, i.e., an optimum sampling frequency both meeting the integer period truncation and meeting no spectrum leakage, by a three-spectral line method; and

S400 resampling the signal to obtain a frequency and amplitude value composition of each harmonic.

Further, in step S100, specifically, an operating frequency f is directly calculated through a formula f=np/60, and sampling is performed by using 2n times of a fundamental frequency estimated value \hat{f}₁ as the initial sampling frequency.

Further, before step S100, the following step is further included:

step S000 obtaining a rotating speed signal fed back by a tested high-speed motor.

Further, the optimum sampling frequency has a plurality of values and is in periodic change.

Further, for the period change of the optimum sampling frequency, a period is gradually increased along with frequency increase.

The disclosure has the beneficial effects that the disclosure designs the Fourier analysis method with the variable sampling frequency. The initial sampling frequency can be fast estimated according to the rotating speed signal. Then, according to a calculation algorithm, the optimum sampling frequency can be fast determined. Acquisition errors and analysis errors of the high-frequency signals can be effectively reduced. The fence effect and the spectrum leakage can be reduced to 0. The analysis precision of the Fourier analysis algorithm can be effectively improved. At the same time, by using this algorithm, high-precision and high-frequency signal acquisition and analysis can be realized by using a smaller sampling frequency, the cost of an acquisition system is reduced, and an analysis speed is accelerated.

### BRIEF DESCRIPTION OF FIGURES

FIG. 1 is a calculation flow diagram of FFT decomposition with a variable sampling frequency.

FIG. 2 is a searching flow diagram of an optimum sampling frequency.

FIG. 3 is a schematic diagram of relationship between sampling frequency change and an amplitude value and a frequency of fundamental waves.

FIG. 4 is a relationship between the sampling frequency change and a fundamental spectral line.

FIG. 5 is a periodic rule shown during the sampling frequency change.

FIG. 6 is a schematic diagram of one condition of main and side lobe distribution.

FIG. 7 is a schematic diagram of another condition of main and side lobe distribution.

FIG. 8 is a schematic diagram of a searching principle based on a bisection method.

### DETAILED DESCRIPTION

The technical solutions in embodiments of the disclosure will be described clearly and completely hereinafter in conjunction with the accompanying drawings in the embodiments of the disclosure, and obviously, the described embodiments are only a part of the embodiments of the disclosure, but not all of them. Based on the embodiments of the disclosure, all other embodiments obtained by those of ordinary skill in the art without creative labor are all within the protection scope of the disclosure.

As shown in FIG. 1, the disclosure provides a Fourier analysis method with a variable sampling frequency, including the following steps:

S100 A to-be-analyzed signal is preliminarily sampled by comparing an initially set sampling frequency, and its fundamental frequency and fundamental amplitude value are further analyzed by Fourier analysis.

S200 The fundamental amplitude value obtained through analysis is preliminarily judged to determine a sampling frequency meeting integer period truncation, and the signal is resampled.

S300 Fourier analysis is performed on the sampled signal, and an optimum sampling frequency, i.e., an optimum sampling frequency both meeting the integer period truncation and meeting no spectrum leakage, is determined by a three-spectral line method.

S400 The signal is resampled to obtain a frequency and amplitude value composition of each harmonic.

In partial preferred embodiments, in step S100, specifically, an operating frequency f is directly calculated through a formula f=np/60, and sampling is performed by using 2n times of a fundamental frequency estimated value \hat{f}₁ as the initial sampling frequency.

In partial preferred embodiments, before step S100, the following step is further included:

Step S000 A rotating speed signal fed back by a tested high-speed motor is obtained.

In partial preferred embodiments, in step S300, the sampling frequency is subjected to optimization regulation according to a harmonic frequency and harmonic amplitude value object to be discriminated so as to determine the optimum sampling frequency.

In partial preferred embodiments, the optimum sampling frequency has a plurality of values and is in periodic change.

In partial preferred embodiments, for the period change of the optimum sampling frequency, a period is gradually increased along with frequency increase.

Specifically, referring to FIG. 1, according to the rotating speed signal fed back by the tested high-speed motor, the operating frequency f is directly calculated by the formula f=np/60. In order to ensure the requirements of the integer period truncation and the sequence length at the same time, sampling can be performed by using 2n times of the fundamental frequency estimated value \hat{f}₁ as the initial sampling frequency. At the same time, the final sampling sequence length also needs to be controlled to N=2p(p>n), i.e., a signal period number is 2p−n, and is recorded as Nₚ. For m-time harmonic, the period number in the sequence is m×Nₚ. It should be noted that 2n points of the fundamental waves are sampled in one period, and only 2n/m points of the m-time harmonic are sampled in one period. When the number of times of the harmonic is greater, the sampling theorem may be not met, so when the sampling frequency is set, n needs to be properly regulated according to the characteristics of the motor to ensure that it meets the following formula:

$$\frac{{2}^{n}}{{m}_{max}} \geq 2. \qquad ( 1 )$$

In the formula, mₘₐₓ is a highest number of times of the harmonic required to be analyzed.

If \hat{f}₁=f₁, the practical fundamental frequency should correspond to a (2^{p-n})^{th} spectral line, spectral line, at the moment, the frequency of the m-time harmonic corresponds to a (m×2^{p-n})^{th} spectral line, and the condition of coinciding with a frequency unit is met. However, because the estimated value fed back by the rotating speed has errors, a spectrum leakage result certainly occurs. In order to reduce the spectrum leakage to the maximum degree, the method obtains different signal sample sequences by changing the sampling frequency, performs Fourier analysis by using these sample sequences, and seeks a maximum value of amplitude value results. When the amplitude value reaches the maximum value, the spectrum leakage is almost totally eliminated. The continuously corrected sampling frequency gradually approaches to the optimum sampling frequency fₛₒₚ=f₁×2^{p-n}.

Illustration is made in conjunction with FIG. 1. In FIG. 1, the three-spectral line analysis is a low-calculation-amount method used to replace FFT. It can be known from the above analysis that elimination of the spectrum leakage of all harmonic components can be completed to the maximum degree only by optimizing the fundamental frequency. Therefore, after the sampling frequency is changed each time, attention only needs to be paid on the amplitude value and frequency condition of a fundamental frequency component, and FFT for completing full frequency-domain calculation is not needed. For the three-spectral line analysis, spectral line positions in a new analysis result can be estimated on the basis of the previously obtained fundamental frequency information.

$$k = [ \frac{{\hat{f}}_{1}}{\frac{{f}_{1}^{*}}{{2}^{p - n}}} ] . \qquad ( 2 )$$

In the formula, [ ] is an integer and can be rounded. The amplitude value A*(k) of a corresponding spectral line is solved. Its calculation method is shown as follows:

$$\begin{matrix}Re = {\sum }_{n = 0}^{N - 1} x ( n \cdot Ts ) \cdot cos ( \frac{2 π nk}{N} ) , & ( 3 ) \\ Im = {\sum }_{n = 0}^{N - 1} x ( n \cdot Ts ) \cdot sin ( \frac{2 π nk}{N} ) , and & ( 4 ) \\ {A}^{*} ( k ) = \sqrt{{Re}^{2} + {Im}^{2}} . & ( 5 )\end{matrix}$$

However, a difference between \hat{f}₁ and the practical fundamental frequency f₁ may cause errors in results of a rounding function, so that an order difference of the corresponding spectral line positions is 1, i.e. the calculated spectral lines are spectral lines at two sides of a main lobe. In order to avoid such errors, the amplitude values of the left and right adjacent spectral lines of a k^{th} spectral line are usually calculated, and a maximum value of the three values is found to be used as the estimated value of the fundamental frequency amplitude value. If the sampling frequency is changed again in a subsequent step, the calculated spectral line positions do not necessarily have errors. Therefore, the amplitude values of the three spectral lines do not need to be calculated each time. For this purpose, a start threshold for the three-spectral line analysis is set:

$${A}_{t} = \frac{{A}^{*} ( k )}{\sqrt{2}} . \qquad ( 6 )$$

In the formula, Aₜ is the start threshold. When the amplitude value of the spectral line obtained through calculation is smaller than Aₜ, its sidelobes and main lobe are almost identical. It shows that the spectral line is certainly not the main lobe, and the main lobe needs to be found through other calculation. The frequency unit corresponding to the main lobe is a newly obtained fundamental frequency analysis result:

$${f}_{1}^{*} = \frac{k \cdot {\hat{f}}_{1}}{{2}^{p - n}} . \qquad ( 7 )$$

According to the newly obtained fundamental frequency value f*₁, a new sampling frequency 2″×f*₁ is defined according to the previous setting.

Referring to FIG. 3, in FIG. 3, a group of fundamental waves with a frequency of 500 Hz and an amplitude value of 10 V are sampled at a sampling frequency of 8000 Hz. Triple harmonics (with a frequency of 1500 Hz and an amplitude value of 3.3 V) and quintuple harmonics (with a frequency of 2500 Hz and an amplitude value of 1.7 V) are included. n=4, and p=9 are set, and their analysis results are taken. It can be seen from FIG. 3 that the amplitude value of each frequency component may show a parabola-like fluctuation rule along with the sampling frequency change. Additionally, a fluctuation period of the harmonics is obviously much smaller than that of the fundamental waves. When the fundamental waves reach a peak value, each harmonic can certainly reach a peak value, not vice versa. If the change range of the sampling frequency is continuously expanded, it can be found that the fluctuation period of the amplitude value can gradually increase along with the sampling frequency increase. It is illustrated in FIG. 4 that by sampling the signal with the fundamental frequency of 500 Hz with 8 kHz, the sequence length of 512 corresponds to 32 periods. At the moment, the fundamental frequency corresponds to a 32^{nd} spectral line on a frequency axis. The spectrum leakage influence is also eliminated for its adjacent peak values, so that the fundamental frequency certainly coincides with the frequency unit. Due to the sampling frequency change, the frequency unit may correspondingly change. Therefore, the fundamental frequency corresponding to the peak values at the left and right sides are just a 33^{rd} spectral line and a 31^{st} spectral line. Identically, based on the above, it may also be known that the fundamental frequency corresponding to a right side wave trough value adjacent to 8 kHz shall be just in the center between the 32^{nd} and 33^{rd} spectral lines, and the fundamental frequency corresponding to its adjacent left side wave trough value shall be just in the center between the 31^{st} and 32^{nd} spectral lines. FIG. 5 illustrates located positions of different sampling frequencies.

Referring to FIG. 2, FIG. 6 and FIG. 7, an amplitude value of a left side spectral line is greater than an amplitude value of a right side spectral line in FIG. 6, and it shows that a real value of the fundamental frequency is between the main lobe and the left side sidelobe. Identically, the condition in FIG. 7 corresponds to a real value of the fundamental frequency between the main lobe and the right side sidelobe. In such a mode, the position relationship between 2ⁿ×f*₁ and fₛₒₚ can be judged. Moreover, the amplitude values of the main lobe and the sidelobes can further be used to correct an obtained measured value of the fundamental frequency. For the condition in FIG. 6, judgment is corrected as follows:

$$\begin{matrix}{f}_{1}^{**} = {f}_{1}^{*} - {λ}_{l} \cdot \frac{{f}_{1}^{*}}{{2}^{p - n}} , and & ( 8 ) \\ {λ}_{l} = \frac{{A}^{*} ( k - 1 )}{\sqrt{{{A}^{*} ( k - 1 )}^{2} + {{A}^{*} ( k )}^{2} + {{A}^{*} ( k + 1 )}^{2}}} . & ( 9 )\end{matrix}$$

For the condition in FIG. 7, the frequency is changed as follows:

$$\begin{matrix}{f}_{1}^{**} = {f}_{1}^{*} + {λ}_{r} \cdot \frac{{f}_{1}^{*}}{{2}^{p - n}} , and & ( 10 ) \\ {λ}_{r} = \frac{{A}^{*} ( k + 1 )}{\sqrt{{{A}^{*} ( k - 1 )}^{2} + {{A}^{*} ( k )}^{2} + {{A}^{*} ( k + 1 )}^{2}}} . & ( 11 )\end{matrix}$$

In the formula, f**₁ is a corrected fundamental frequency value. A*(k), A*(k−1) and A*(k+1) are respectively amplitude values of spectral lines of the main lobe and the left and right side sidelobes. λ and λᵣ are respectively correction coefficients when the sampling frequency is leftwards and rightwards corrected.

Referring to FIG. 2 and FIG. 8, after corrosion by the three-spectral line method, a deviation between f**₁ and the real value of the fundamental frequency is very small, but if the sampling frequency is continuously optimized by the three-spectral line method, it possibly causes misconvergence finally. The optimization of the three-spectral line method is rough, and the amplitude is greater, and oscillation of a final optimization value around the practical value may be caused, but convergence cannot be realized. Therefore, a precise position of the optimum sampling frequency is considered to be fast locked by a bisection method.

The bisection method is a fast method suitable for searching in a large data volume interval. By the principle of a bisection region, the region can be reduced at an exponential speed. As shown in FIG. 8, the number of calculation times no depends on a searching interval L=[Fₐ, F_{b}] and a calculation precision e:

$${n}_{0} = [ {log}_{2} ( \frac{L}{e} ) ] . \qquad ( 12 )$$

A rounding function in the formula needs positive rounding. The sampling frequency after twice correction is very close to the optimum sampling frequency, so that the searching interval of the bisection method can be greatly compressed to reduce the number of searching times. As mentioned above, the corrected 2″×f**₁ is certainly distributed between fₛ^{c} and fₛ^{d}, so that the searching interval can be calculated by subtracting fₛ^{c} by fₛ^{d}. However, the searching interval is too large, and a specific difference value between 2″×f**₁ and the optimum sampling frequency fₛₒₚ is unknown, it is not suitable to reduce the searching interval blindly, and the searching interval can be further reduced by using the principle of correcting the fundamental frequency by three spectral lines. A new sequence obtained through sampling by using 2″×f**₁ is analyzed by using the three-spectral line method again. Identically, according to the above steps, a sampling frequency correction direction is judged according to amplitude values of the sidelobes. Then, a correction coefficient 2 of the fundamental frequency is solved by using an amplitude value proportion of the main lobe and the sidelobes:

$$λ = \{ \begin{matrix}\frac{{A}^{**} ( k - 1 )}{\sqrt{{{A}^{**} ( k - 1 )}^{2} + {{A}^{**} ( k )}^{2} + {{A}^{**} ( k + 1 )}^{2}}} & {A}^{**} ( k - 1 ) \geq {A}^{**} ( k + 1 ) \\ \frac{{A}^{**} ( k + 1 )}{\sqrt{{{A}^{**} ( k - 1 )}^{2} + {{A}^{**} ( k )}^{2} + {{A}^{**} ( k + 1 )}^{2}}} & {A}^{**} ( k + 1 ) \geq {A}^{**} ( k - 1 ) .\end{matrix} \qquad ( 13 )$$

In the formula, A**(k), A**(k−1) and A**(k−1) are amplitude value results of the main lobe and sidelobes of three-spectral line analysis performed again. In order to ensure that the optimum sampling frequency fₛₒₚ is in the interval, a correction amount of the fundamental frequency is increased to twice.

End points of another corresponding interval are as follows:

$$\{ \begin{matrix}{F}_{a} = {2}^{n} \times ( {f}_{1}^{**} - L ) & {F}_{b} = {f}_{1}^{**} \times {2}^{n} \\ {F}_{b} = {2}^{n} \times ( {f}_{1}^{**} + L ) & {F}_{a} = {f}_{1}^{**} \times {2}^{n} .\end{matrix} \qquad ( 14 )$$

After the searching interval is determined, one half of a sum of sampling frequencies of two end points is taken according to the principle of the bisection method to be used as a new sampling frequency. An amplitude value Aₒₚ of the main lobe of the new signal sequence based on the new sampling frequency is calculated by using the three-spectral line method. A different value between Aₒₚ and the amplitude value of the main lobe corresponding to the sampling frequencies of the two end points is as follows:

$$\begin{matrix}{f}_{sop} = \frac{{F}_{a} + {F}_{b}}{2} , & ( 15 ) \\ {Δ}_{a} = {A}_{op} - {A}_{a} , and & ( 16 ) \\ {Δ}_{b} = {A}_{op} - {A}_{b} . & ( 17 )\end{matrix}$$

According to sizes of Δₐ and Δ_{b}, the end points of the interval can be determined and updated, and value reassignment is performed:

$$\{ \begin{matrix}\begin{matrix}{F}_{a} = {f}_{sop} \\ {F}_{b} = {F}_{b} \end{matrix} & {Δ}_{a} > {Δ}_{b} \\ \begin{matrix}{F}_{a} = {F}_{a} \\ {F}_{b} = {f}_{sop}\end{matrix} & {Δ}_{a} < {Δ}_{b} .\end{matrix} \qquad ( 18 )$$

A calculation precision is set to be 10⁻⁴ grade. When the difference value Δ_{ab}=|Aₐ−A_{b}| between the amplitude value results of the main lobe corresponding to the sampling frequencies of the two end points of a new interval is smaller than the precision, the searching of the bisection method can be considered completed.

What is claimed is:

1. A Fourier analysis method with a variable sampling frequency, comprising the following steps:
S100: preliminarily sampling a to-be-analyzed rotating speed signal by comparing an initially set sampling frequency, and further analyzing its fundamental frequency and fundamental amplitude value by Fourier analysis;
S200 preliminarily judging the fundamental amplitude value obtained through analysis to determine a sampling frequency meeting integer period truncation, and resampling the rotating speed signal to obtain a sampled signal;
S300 performing Fourier analysis on the sampled signal, and determining an optimum sampling frequency, wherein the optimum sampling frequency being both meeting the integer period truncation and meeting no spectrum leakage, by a three-spectral line method; and
S400 resampling the signal to obtain a frequency and amplitude value composition of each harmonic.

2. The Fourier analysis method with a variable sampling frequency according to claim 1, wherein in step S100, an operating frequency f is directly calculated through a formula f=np/60, and sampling is performed by using 2n times of a fundamental frequency estimated value \hat{f}₁ as an initial sampling frequency.

3. The Fourier analysis method with a variable sampling frequency according to claim 2, wherein before step S100, further comprising the following step:
step S000 obtaining a rotating speed signal fed back by a tested high-speed motor.

4. The Fourier analysis method with a variable sampling frequency according to claim 2, wherein the optimum sampling frequency has a plurality of values and is in periodic change.

5. The Fourier analysis method with a variable sampling frequency according to claim 3, wherein for the period change of the optimum sampling frequency, a period is gradually increased along with frequency increase.
